(19) United States
(12) Patent Application Publication
(10) Pub. No.: US 2014/0375652 A1
(43) Pub. Date: Dec. 25, 2014

(54) APPARATUS FOR MEASURING STATIC ELECTRICITY AND METHOD FOR MEASURING STATIC ELECTRICITY

(71) Applicant: SAMSUNG DISPLAY CO., LTD., Yongin-City (KR)

(72) Inventors: In Su Jeon, Incheon (KR); Min Woo Kim, Busan (KR); Kyung Pil Yang, Gyeonggi-do (KR); Hyun Sik Choi, Chungcheongnam-do (KR); Hong Sik Yoon, Gyeonggi-do (KR)

(73) Assignee: SAMSUNG DISPLAY CO., LTD., Yongin-City (KR)

(21) Appl. No.: 14/148,792

(22) Filed: Jan. 7, 2014

(30) Foreign Application Priority Data
Jun. 24, 2013 (KR) 10-2013-0072414

(51) Int. Cl. G06T 11/20; G01R 29/12

(52) U.S. Cl. CPC G06T 11/206; G01R 29/12
USPC 345/440; 324/457

(57) ABSTRACT

An apparatus for measuring static electricity on a substrate includes a measuring unit, an information processing unit, and a display unit. The measuring unit measures first static electricity information from the substrate. The information processing unit calculates a static electricity distribution state of the substrate using the first static electricity information. The display unit displays a graphic image representing the static electricity distribution state. The information processing unit includes a calculating unit and a controller. The calculating unit estimates second static electricity information using the first static electricity information. The controller calculates the static electricity distribution state of the substrate using the first static electricity information and the second static electricity information.

### CROSS-REFERENCE TO RELATED APPLICATION

This application claims priority under 35 U.S.C. §119 to Korean Patent Application No. 10-2013-0072414, filed on Jun. 24, 2013 in the Korean Intellectual Property Office, the disclosure of which is incorporated by reference herein in its entirety.

### TECHNICAL FIELD

The present invention relates to an apparatus for measuring static electricity and a method for measuring static electricity.

### DISCUSSION OF RELATED ART

In manufacturing display devices on a substrate, static electricity generated by electrification is accumulated on a flat panel wafer or glass due to a high resistance of the substrate. For example, When the flat panel wafer is in contact with a charged material, static electricity is created in the flat panel wafer with the same polarity as that of the charged material. Due to friction, static electricity may be generated in a flat panel wafer. In an ion injection process, ions, electrons, alpha particles, and the like which collide with a flat panel wafer create static electricity in the wafer. In addition, when an flat panel wafer is positioned within an electric field, static electricity is created due to the electric field.

The static electricity serves to collect particles on a flat panel wafer in a manufacturing process. Such particles may cause defects in the manufacturing process. In addition, when the static electricity is discharged with a level of several hundreds or several thousands of volts, such discharged electricity may cause destroy metals or thin oxides formed on the flat panel wafer.

### SUMMARY

According to an exemplary embodiment of the present invention, an apparatus for measuring static electricity on a substrate includes a measuring unit, an information processing unit, and a display unit. The measuring unit measures first static electricity information from the substrate. The information processing unit calculates a static electricity distribution state of the substrate using the first static electricity information. The display unit displays a graphic image representing the static electricity distribution state. The information processing unit includes a calculating unit and a controller. The calculating unit estimates second static electricity information using the first static electricity information. The controller calculates the static electricity distribution state of the substrate using the first static electricity information and the second static electricity information.

A method for measuring static electricity is provided. A measuring unit is disposed on a substrate. The measuring unit includes a plurality of static electricity sensors. First static electricity information is measured using the plurality of the static electricity sensors. Each static electricity sensor measures the static electricity information from a corresponding sensing region of the substrate. Second static electricity information is estimated using the first static electricity information. The second static electricity information corresponds to a non-sensing region adjacent to the corresponding sensing region. A static electricity distribution state of the substrate is calculated by combining the first static electricity information and the second static electricity information.

### BRIEF DESCRIPTION OF THE DRAWINGS

These and other features of the inventive concept will become more apparent by describing in detail exemplary exemplary embodiments thereof with reference to the accompanying drawings of which:

FIG. 1 is a block diagram of an apparatus for measuring static electricity according to an exemplary embodiment of the present invention;

FIG. 2 is a top plan view of a measuring unit according to an exemplary embodiment of the present invention;

FIG. 3 is a partial perspective view of the apparatus for measuring static electricity according to an exemplary embodiment of the present invention;

FIG. 4 is a top plan view of a substrate, which is a measurement target of the apparatus for measuring static electricity according to an exemplary embodiment of the present invention;

FIG. 5 is a partial enlarged view of region A of FIG. 4;

FIG. 6 is a partial enlarged view of region B1 of FIG. 4;

FIG. 7 is a partial enlarged view of region B2 of FIG. 4;

FIG. 8 is a partial enlarged view of region B3 of FIG. 4;

FIG. 9 is a top plan view of a display unit of the apparatus for measuring static electricity according to an exemplary embodiment of the present invention;

FIG. 10 is a top plan view of a display unit of an apparatus for measuring static electricity according to an exemplary embodiment of the present invention;

FIG. 11 is a top plan view of a display unit of an apparatus for measuring static electricity according to an exemplary embodiment of the present invention;

FIG. 12 is a top plan view of a display unit of an apparatus for measuring static electricity according to an exemplary embodiment of the present invention;

FIG. 13 is a block diagram of an apparatus for measuring static electricity according to an exemplary embodiment of the present invention;

FIG. 14 is a block diagram of an apparatus for measuring static electricity according to an exemplary embodiment of the present invention;

FIG. 15 is a top plan view illustrating a position of a photographing unit of the apparatus for measuring static electricity according to an exemplary embodiment of the present invention; and

FIG. 16 is a top plan view of a display unit of an apparatus for measuring static electricity according to an exemplary embodiment of the present invention.

### DETAILED DESCRIPTION OF THE EXEMPLARY EMBODIMENTS

Exemplary embodiments of the inventive concept will be described below in detail with reference to the accompanying drawings. However, the inventive concept may be embodied in different forms and should not be construed as limited to the embodiments set forth herein. In the drawings, the thickness of layers and regions may be exaggerated for clarity. It will also be understood that when a layer is referred to as being on another layer or substrate, it may be directly on the other layer or substrate, or intervening layers may also be present. Like reference numerals may refer to the like elements throughout the specification and drawings.

It will be understood that when an element or layer is referred to as being “on”, “connected to” or “coupled to” another element or layer, it can be directly on, connected or coupled to the other element or layer or intervening elements or layers may be present.

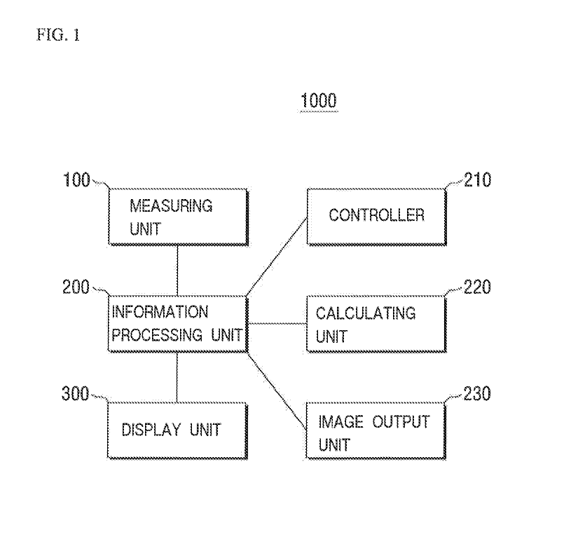

FIG. 1 is a block diagram of an apparatus for measuring static electricity according to an exemplary embodiment of the present invention.

Referring to FIG. 1, an apparatus 1000 for measuring static electricity according to an exemplary embodiment of the present invention includes a measuring unit 100, an information processing unit 200 for calculating a static electricity distribution state on a substrate 10, and a display unit 300 for displaying the static electricity distribution state.

The information processing unit 200 includes a calculating unit 220 for estimating static electricity information of a region adjacent to a region measured using the measuring unit 100 and a controller 210 for calculating a static electricity distribution state on the substrate based on the static electricity information measured by the measuring unit 100 and the static electricity information estimated by the calculating unit 220.

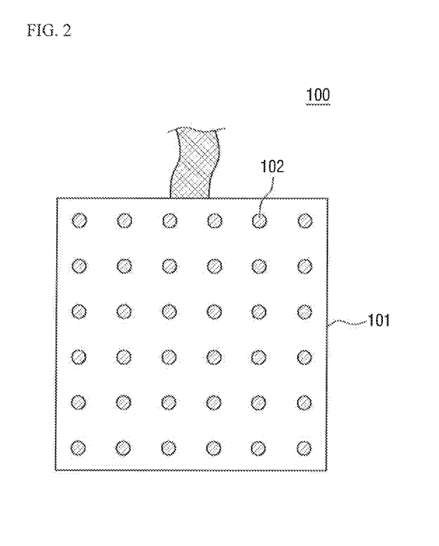

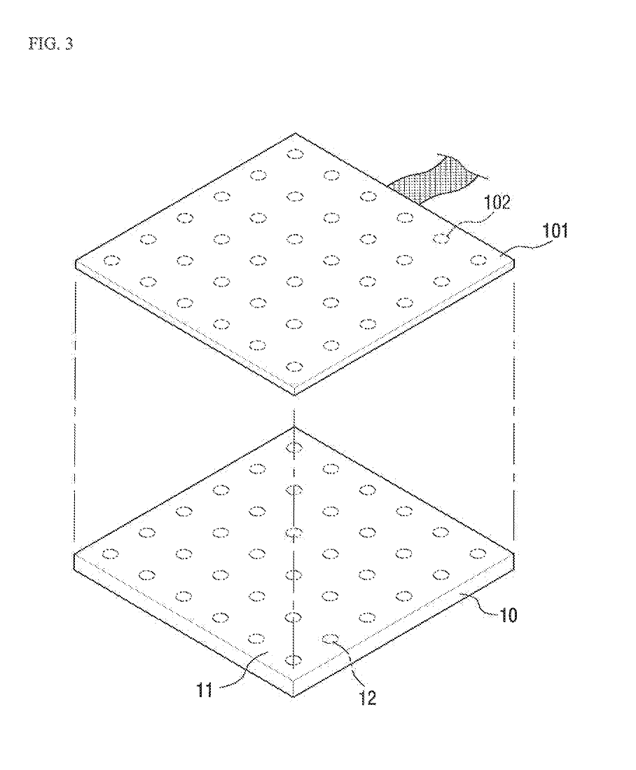

The measuring unit 100 measures static electricity information on the substrate. The measuring unit 110 will be described in detail with reference to FIGS. 2 and 3. FIG. 2 is a top plan view of the measuring unit 100 of FIG. 1 according to an exemplary embodiment, and 3 is a partial perspective view of the apparatus 1000 of FIG. 1 for measuring static electricity according to an exemplary embodiment of the present invention.

Referring to FIGS. 2 and 3, the measuring unit 100 includes the static electricity sensors 102 for measuring the static electricity information on the substrate. The static electricity sensor 102 may measure a static electricity value of a single point or a single region on the substrate 10. The type of static electricity sensor 102 is not limited, and may include all of the static electricity sensors, which are currently commercialized, or which will be commercialized according to a future development of a technique.

The measuring unit 100 includes a plurality of static electricity sensors 102 disposed on a base plate 101. The sensors 102 face the substrate 10. The plurality of static electricity sensors 102 may be disposed in a matrix form while being spaced apart from each other at a predetermined interval. However, the arrangement of the static electricity sensors 102 is not limited thereto, and the static electricity sensors 102 may be disposed in various forms. Alternatively, the plurality of static electricity sensors 102 may be disposed to be opposite to the substrate 10. The base plate 101 may be spaced apart from the substrate 10, which is a measurement target, at a predetermined interval, or may be in contact with the substrate 10.

A size of the base plate 101 may correspond to a size of the substrate 10. For example, the size of the base plate 101 may be substantially the same as the size of the substrate 10. However, the size of the base plate 101 is not limited thereto, and may be smaller or larger than the size of the substrate 10. In a case where the size of the base plate 101 is substantially the same as the size of the substrate 10, it is possible to more accurately recognize the static electricity distribution state of the entire regions of the substrate 10.

Each static electricity sensor 102 measures a static electricity value at a corresponding region of the substrate. For the convenience of description, the corresponding region is defined as a sensing region 12. The remaining region except for the sensing region 12 is defined as the non-sensing region 11. The sensing region 12 of the substrate 10 is a predetermined point or region according to the arrangement of the static electricity sensors 102. A shape or a size of the sensing region 12 may include, but is not limited to, a dot shape or a circular shape. Each static electricity sensor 102 serves to measure static electricity information of the sensing region 12 corresponding to each static electricity sensor 102.

The number of sensing regions 12 is the same as the number of static electricity sensors 102, but the number of sensing regions 12 is not limited thereto.

The static electricity information measured by the measuring unit may be a relative value based on an absolute static electricity value or a predetermined static electricity value of each sensing region 12 that each static electricity sensor 102 measures.

The substrate 10 may be a unit display substrate, and may be a mother substrate which is not cut and divided into a plurality of unit display substrates. The substrate 10 may be one sheet of the substrate, but may include a plurality of stacked substrates.

The substrate 10 may include an insulating substrate. The insulating substrate may be formed of a transparent glass material having transparent SiO₂. Alternatively, the substrate 10 may be formed of an opaque material, or may also be formed of a plastic material. Further, the substrate 10 may be formed of a flexible substrate which is bendable, foldable, or rollable. The information processing unit 200 serves to calculate the static electricity distribution state on the substrate 10 based on the static electricity information measured by the measuring unit 100.

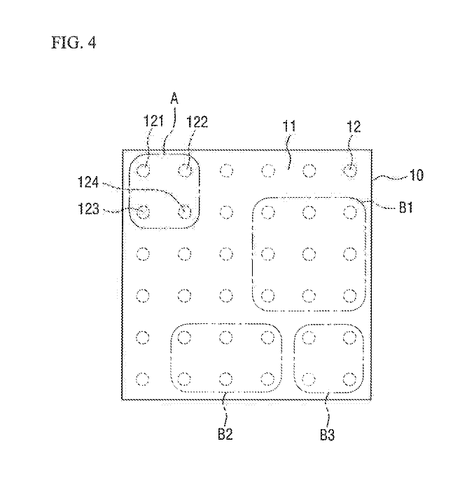

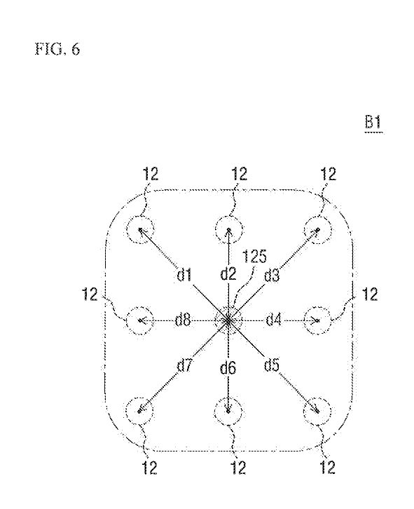

The information processing unit 200 includes the calculating unit 220 for estimating static electricity information of the non-sensing region 11 or another adjacent sensing region 12 based on the static electricity information of the plurality of sensing regions 12 measured by the plurality of static electricity sensors 102. The calculating unit 220 serves to estimate the static electricity information of the non-sensing region 11 or another adjacent sensing region 12 by using various statistical methods. The method of estimating the static electricity information of the non-sensing region 11 or another adjacent sensing region 12 by the calculating unit 220 includes, but is not limited to, interpolation, a regression analysis, and a general linear model (GLM). The calculating unit 220 will be described in detail with reference to FIGS. 4 and 6.

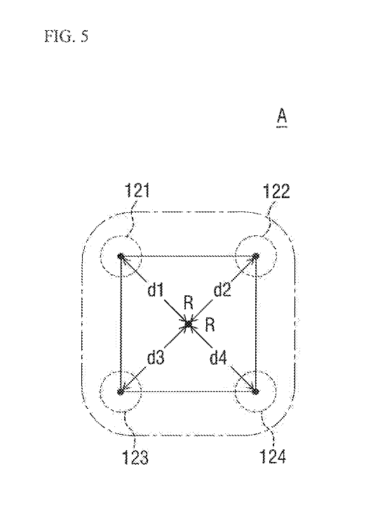

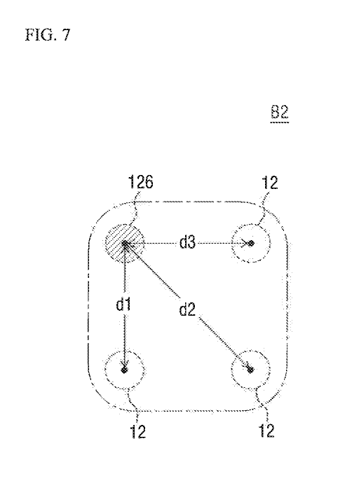

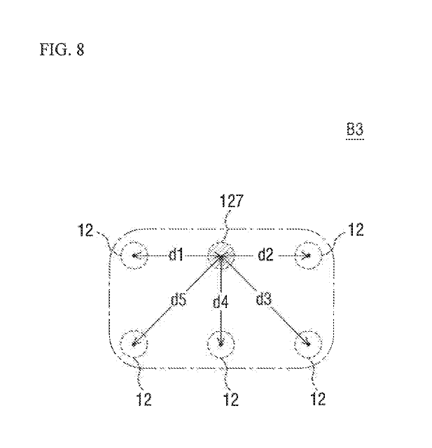

FIG. 4 is a top plan view of the substrate, which is the measurement target of the apparatus for measuring static electricity according to an exemplary embodiment of the present invention. FIG. 5 is a partial enlarged view of region A of FIG. 4. FIG. 6 is a partial enlarged view of region B1 of FIG. 4. FIG. 7 is a partial enlarged view of region B2 of FIG. 4. FIG. 8 is a partial enlarged view of region 133 of FIG. 4.

The calculating unit 220 of FIG. 1 serves to estimate the static electricity information of the non-sensing region 11 based on the static electricity information of the sensing region 12.

For the convenience of description, the plurality of static electricity sensors are defined as a first static electricity sensor, a second static electricity sensor spaced apart from the first static electricity sensor in a first direction, a third static electricity sensor spaced apart from the first static electricity sensor in a second direction vertical to the first direction, and a fourth static electricity sensor spaced apart from the third static electricity sensor in the first direction. Further, first to fourth sensing regions 121 to 124 corresponding to the first to fourth static electricity sensors are defined on the substrate 10. The first to fourth sensing regions 121 to 124 may be positioned in a vertical lower portion or a vertical upper portion of the first to fourth static electricity sensors, but are not limited thereto.

Further, a first region surrounding a center of the first to fourth sensing regions 121 to 124 is defined. For example, the first region may be a region surrounded by a first line segment connecting a center of the first sensing region 121 and a center of the second sensing region 122, a second line segment connecting the center of the second sensing region 122 and a center of the fourth sensing region 124, a third line segment connecting the center of the fourth sensing region 124 and a center of the third sensing region 123, and a fourth line segment connecting the center of the third sensing region 123 and the center of the first sensing region 121.

The calculating unit 220 may estimate static electricity information of a predetermined point within the first region based on the static electricity information of the first to fourth sensing regions 121 to 124 measured by the first to fourth static electricity sensors. Further, static electricity information of the entire region of the first region may be obtained by estimating the static electricity information on points within the first region.

For example, the calculating unit 220 may estimate static electricity information of a predetermined point (the predetermined point is designated by “R” for convenience of the description) on the substrate by utilizing various statistical methods or algorithms using a single variable or a plurality of variables. The predetermined point corresponds to a point of the non-sensing region 11.

The calculating unit 220 calculates an absolute or relative static electricity value at the predetermined point R using distances d1 to d4 from the first to fourth sensing regions 121 to 124 to the predetermined point R, and absolute or relative static electricity values of the first to fourth sensing regions 121 to 124 measured using the measuring unit 100. For example, the calculating unit 220 may estimate the static electricity information of the predetermined point R on the substrate 10 based on at least one of the first distance d1 from the center of the first sensing region 121 to the predetermined point R, the second distance d2 from the center of the second sensing region 122 to the predetermined point R, the third distance d3 from the center of the third sensing region 123 to the predetermined point R, and the fourth distance d4 from the center of the fourth sensing region 124 to the predetermined point R, and at least one of the static electricity information of the first to fourth sensing regions 121 to 124. The present invention is not limited thereto, and the calculation unit 220 may use more variables.

The calculating unit 220 may utilize various statistical methods based on the plurality of variables. The statistical method or algorithm may include, but is not limited to, interpolation, a regression analysis, or a general linear model (GLM).

Referring to FIGS. 4, and 6 to 8, the calculating unit 220 may also estimate the static electricity information of an adjacent sensing region 12 based on the static electricity information of the sensing region 12.

Some of the plurality of static electricity sensors may be defective. Hereinafter, the defective sensor, which is not normally operated, is referred to as an abnormal sensor. In this case, the calculating unit 220 may estimate static electricity information of the abnormal sensor based on the static electricity information of a sensing region which is adjacent to a sensing region measured by the abnormal sensor.

FIG. 6 shows eight sensing regions 12 adjacent to a sensing region 125 corresponding to the abnormal sensor. In this case, the calculating unit 220 estimates static electricity information of the sensing region 125 using the static electricity information of the adjacent eight sensing regions 12 and distances between the adjacent sensing regions 12 and the sensing region 125 of the abnormal sensor as variables. The calculating unit 220 is not limited thereto, and may estimate the static electricity information of the sensing region 125 based on static electricity information of some sensing regions among the eight sensing regions 12.

FIG. 7 shows three sensing regions 12 adjacent to a sensing region 126 corresponding to the abnormal sensor. The abnormal sensor may be positioned at a corner of the measuring unit 100. In this case, the three adjacent sensing regions 12 are adjacent to the sensing region 126 that is positioned at a corner of the substrate 10. The calculating unit 220 estimates static electricity information of the sensing region 126 using the static electricity information of the three sensing regions 12 and distances between the adjacent sensing regions 12 and the sensing region 126 of the abnormal sensor as variables. The calculating unit 220 is not limited thereto, and may estimate the static electricity information of the sensing region 126 based on static electricity information of some sensing regions among the three sensing regions 12.

FIG. 8 shows five sensing regions 12 adjacent to a sensing region 127 corresponding to the abnormal sensor. The abnormal sensor may be positioned at a side portion of the measuring unit 100. In this case, the five adjacent sensing regions 12 are adjacent to the sensing region 127 that is positioned at a side of the substrate 10. The calculating unit 220 estimates static electricity information of the sensing region 127 using the static electricity information of the five sensing regions 12 and distances between the adjacent sensing regions 12 and the sensing region 127 of the abnormal sensor as variables. The calculating unit 220 is not limited thereto, and may estimate the static electricity information of the sensing region 127 based on static electricity information of some sensing regions among the three sensing regions 12.

The information processing unit 200 includes the controller 210 for calculating the static electricity distribution state on the substrate based on the static electricity information measured by the plurality of static electricity sensors and the static electricity information estimated by the calculating unit 220. For example, the controller 210 calculates the static electricity distribution state of the entire regions on the substrate 10 by synthesizing the static electricity information measured by the plurality of static electricity sensors and the static electricity information estimated by the calculating unit 200. For example, the static electricity distribution state may include digitized data.

The information processing unit 220 includes an image output unit 230. The image output unit 230 displays the static electricity distribution state calculated by the controller 210 as an image to the outside of the apparatus 1000. For example, the image may include various forms including, but are not limited to, numbers, colors, a 3D chart, a contour line, or a combination thereof.

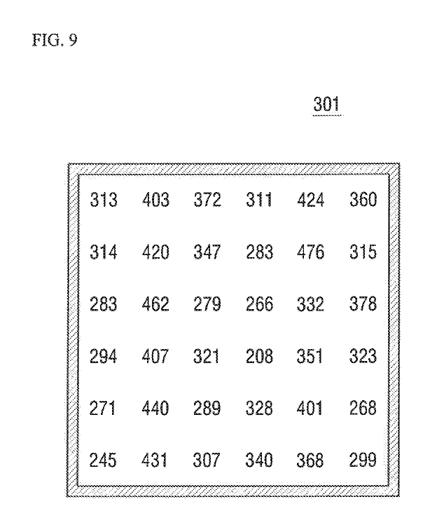

The display unit 300 may include a display panel including a self-emission display panel, such as an organic light emitting diode (OLED), an LED, an inorganic Electro Luminescent (EL) display, a Field Emission Display (FED), a Surface-conduction Electron-emitter Display (SED), a Plasma Display Panel (PDP), or a Cathode Ray Tube (CRT). Alternatively, the display panel may be a non-emissive display panel, such as a Liquid Crystal Display (LCD) or an Electrophoretic Display (EPD). The present invention is not limited thereto, and may include various forms of a display device. The display unit 300 displays, in various forms, the static electricity distribution state of the substrate 10 calculated by the information processing unit 200. This will be described in detail with reference to FIGS. 9 to 12.

FIG. 9 shows an exemplary static electricity distribution state that is displayed on the display unit 300 of FIG. 1. The displayed image includes numbers representing relative values of static electricity.

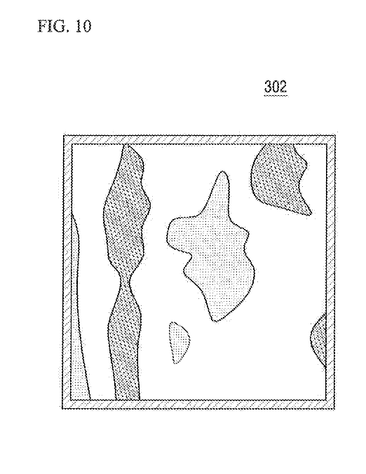

FIG. 10 shows an exemplary static electricity distribution state that is displayed on the display unit 300 of FIG. 1. The displayed image includes colors representing relative values of static electricity. For example, a region having a relative static electricity value that ranges from 0 to 100 may be displayed with a blue color. A region having a relative static electricity value that ranges from 100 to 200 may be displayed with a yellow color. A region having a relative static electricity value that is equal to or larger than 200 may be displayed with a red color. Further, the static electricity distribution state may be displayed to have a tone difference according to the relative static electricity value even within the same color region. For example, the static electricity distribution state may be toned down or toned up according to a numerical value of the blue region.

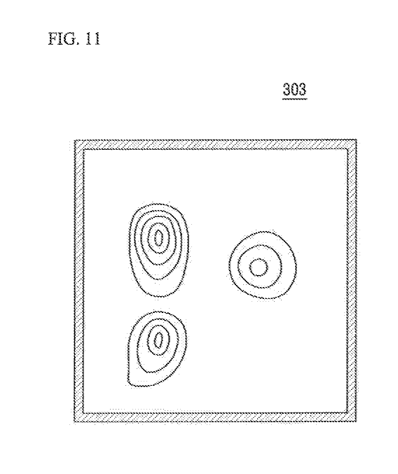

FIG. 11 shows an exemplary static electricity distribution state that is displayed on the display unit 300 of FIG. 1. The displayed image includes contour lines representing relative values of static electricity. Each contour line connects points having the same relative static electricity value.

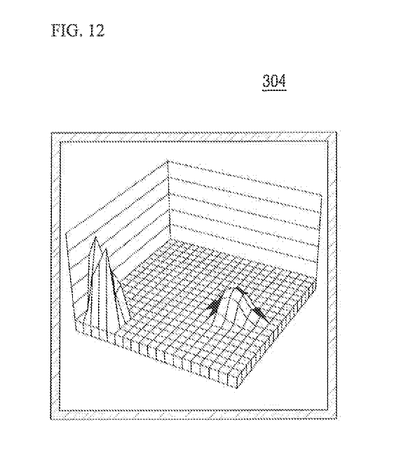

FIG. 12 shows an exemplary static electricity distribution state that is displayed on the display unit 300 of FIG. 1. The displayed image includes a 3D chart, where the heights represent relative values of static electricity.

As described above, an image output unit 230 displays static electricity distributions on the display unit 300 in various images so that it is possible to easily recognize the static electricity distribution state on the substrate 10.

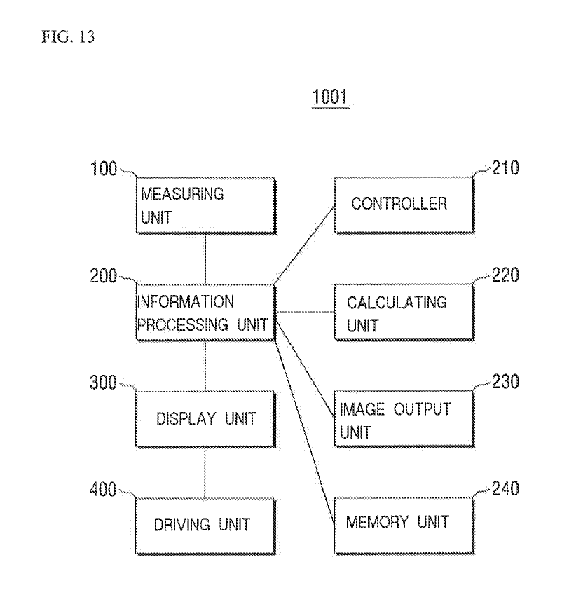

FIG. 13 is a block diagram of an apparatus for measuring static electricity according to an exemplary embodiment of the present invention.

Referring to FIG. 13, an apparatus 1001 is substantially similar to that of FIG. 1, except that the apparatus 1001 of FIG. 13 further includes a driving unit 400, and the information processing unit 200 further includes a memory unit 240.

As described above, the substrate 10 may refer to a substrate having several structures that are disposed on the substrate in a manufacturing process or a completed product. The driving unit 400 applies a voltage to the substrate 10. The driving unit 400 may include a probe unit or various configurations for operating the substrate 10.

A measuring unit 100 measures, in real time, static electricity information on the substrate 10 while applying the voltage onto the substrate 10. For example, a measuring unit 100 may measure a change in the static electricity information of the plurality of sensing regions 12 corresponding to the plurality of static electricity sensors 102. A calculating unit 220 estimates static electricity information of a non-sensing region 11 or another adjacent sensing region 12 using the static electricity information measured, in real time, by the measuring unit 100. A controller 210 calculates changes in the static electricity distribution state according to the operation of the substrate 10 by synthesizing the measured static electricity information and the estimated static electricity information in real time.

In addition, an information processing unit 200 further includes a memory unit 240 for storing the changes in the static electricity distribution state according to the operation of the substrate 10, The memory unit 240 stores the static electricity distribution state according to the operation of the substrate 10, and the stored static electricity distribution state is visualized using a display unit 300. For example, the memory unit 240 stores a static electricity distribution state of the substrate 10 at a time when applying of a voltage to the substrate 10 is started and a static electricity distribution state of the substrate at a time when the applying of the voltage to the substrate 10 is terminated. The change in the static electricity distribution state on the substrate 10 is visualized by the display unit 300.

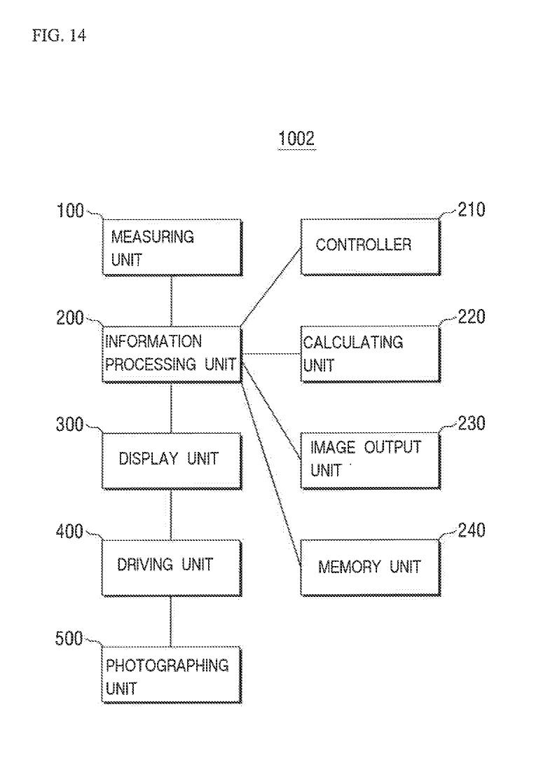

FIG. 14 is a block diagram of an apparatus for measuring static electricity according to an exemplary embodiment of the present invention.

Referring to FIG. 14, an apparatus 1002 is substantially similar to that of FIG. 14, except that the apparatus 1002 of FIG. 14 further includes a photographing unit 500 for photographing an operation image of the substrate 10.

The photographing unit 500 takes pictures of an operation state of the substrate 10. The photographing unit 500 may be a web cam, but is not limited thereto.

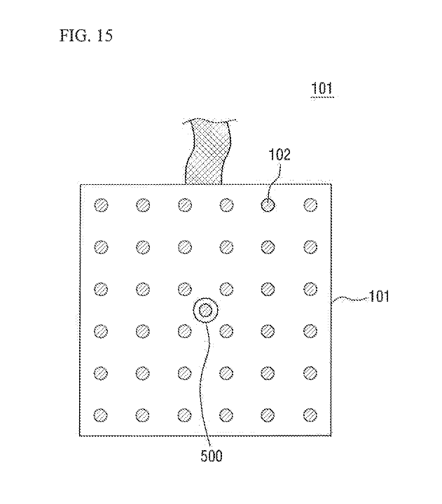

FIG. 15 is a top plan view illustrating a position of the photographing unit installed in the base plate 101 according to an exemplary embodiment of the present invention.

The photographing unit 500 may be disposed to face the substrate 10. Alternatively, the photographing unit 500 may be opposite to the substrate. The photographing unit 500 may be disposed on the base plate of the measuring unit, but is not limited thereto. Further, the photographing unit 500 may be disposed between the plurality of static electricity sensors disposed in the matrix form, and the number of photographing units 500 may be single or plural.

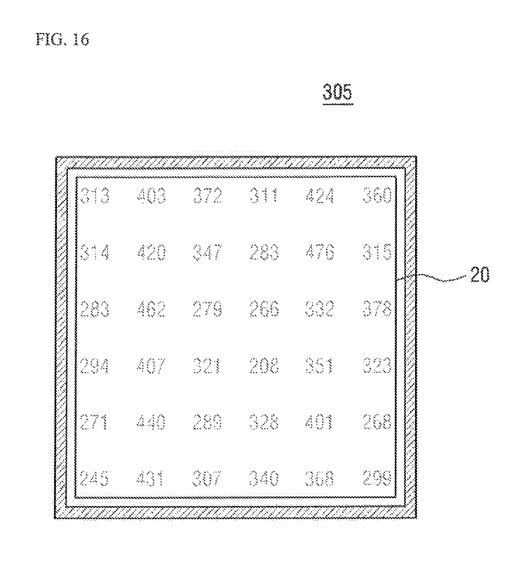

FIG. 16 shows an exemplary static electricity distribution state that is displayed on the display' unit 300 of FIG. 14.

Referring to FIG. 16, the display unit displays an image having an operation image of a substrate and a static electricity distribution state on the substrate. The operation image and the static electricity distribution state are overlapped. The displayed image includes numbers representing relative values of static electricity.

For example, the image photographed by a photographing unit 500 is transmitted to an information processing unit 200. The information processing unit 200 matches the photographed image to a static electricity distribution state calculated by the information processing unit 200. For example, the controller 210 matches the operation image of the substrate 10 to the static electricity information on the substrate 10, and an image output unit 230 generates an composite image of the static electricity distribution state and the operation image of the substrate 10. Further, a part or all of the static electricity distribution state of the substrate may be transparently or opaquely displayed so that the operation image of the substrate 10 and the static electricity distribution state on the substrate 10 are simultaneously viewed.

In a case where the apparatus for measuring static electricity includes the photographing unit 500, it is possible to simultaneously view the operation image of the substrate 10 and the change in the static electricity distribution state according to the operation image of the substrate 10, thereby facilitating to recognize a change in the static electricity distribution state according to an operation state of the substrate 10.

A memory unit 400 stores a change in the static electricity distribution state changing according to the operation of the substrate 10. The memory unit 400 stores the operation image of the substrate photographed by the photographing unit 500 and/or the static electricity distribution state changing according to the operation image of the substrate, and the stored operation image of the substrate 10 and the static electricity distribution state according to the operation image of the substrate 10 are visualized by a display unit 300. In addition, the memory unit 400 stores the composite image of the static electricity distribution state of the substrate 10 and the operation image of the substrate 10.

Hereinafter, a method for measuring static electricity according to an exemplary embodiment of the present invention will be described with reference to the elements represented in FIGS. 1 to 9.

The measuring unit 100 including a plurality of static electricity sensors 102 is disposed on the substrate 10 to measure static electricity information of each sensing region 12. Each sensing region 12 corresponds to each static electricity sensor 102. Non-sensing regions 11 are the remaining regions of the substrate 10, except for the sensing regions 12, Static electricity information of the non-sensing region 11 or another adjacent sensing region 12 is estimated using the static electricity information measured by each static electricity sensor 102. The static electricity information measured by the static electricity sensor 102 and the estimated static electricity information of the non-sensing region 11 or another adjacent sensing region 12 are synthesized to generate static electricity distribution states of the substrate 10. The static electricity distribution state is displayed.

First, the measuring unit 100 including the plurality of static electricity sensors may be disposed on the substrate 10. The plurality of static electricity sensors 102 may be disposed to be opposite to the substrate 10.

In a state where the measuring unit 100 is disposed on the substrate 10, each static electricity sensor 102 measures the static electricity information from its corresponding sensing region 12.

Next, the static electricity information of the non-sensing region 11 or another adjacent sensing region 12 is estimated using the static electricity information measured by each static electricity sensor 102. The estimating of the static electricity information may be performed by the calculating unit 220 using a method including, but is not limited to, interpolation, a regression analysis, or a general linear model (GLM).

Next, the static electricity distribution states of the substrate 10 is generated by synthesizing the static electricity information measured by the static electricity sensor 102 and the estimated static electricity information of the non-sensing region 11 or another adjacent sensing region 12. The synthesizing of the static electricity information is performed using the controller 210 of FIG. 1.

Next, the static electricity distribution state is displayed using various visualization methods. The displaying of the static electricity distribution state is performed using the display unit 300 of FIG. 1. The generation of the image for the static electricity distribution state may be performed by the image output unit 230 of FIG. 1. Hereinafter, a method for measuring static electricity according to an exemplary embodiment of the present invention will be described with reference to FIGS. 10 to 16.

The method for measuring static electricity according to an exemplary embodiment of the present invention may further include a step of operating a substrate 10. The step of operating the substrate 10 may include a step of applying a voltage onto the substrate 10. That is, the static electricity information of each sensing region 12 is measured in a state where the substrate 10 is operated, so that it is possible to measure a change in the static electricity distribution state according to the operation of the substrate 10.

In addition, the method for measuring static electricity according to an exemplary embodiment of the present invention may further include a step of photographing an operation image of the substrate 10. That is, the driving of the substrate 10 may be simultaneously or sequentially performed with the photographing of the operation image of the substrate 10.

The step of displaying the static electricity distribution state in the method for measuring static electricity according to an exemplary embodiment of the present invention may include a step of displaying an image in which the operation image of the substrate 10 overlaps the static electricity distribution state of the substrate 10. In order to display the image in which the operation image of the substrate 10 overlaps the static electricity distribution state of the substrate 10, the method for displaying static electricity according to another exemplary embodiment of the present invention may further include: a step of matching the photographed operation image of the substrate 10 and the calculated static electricity distribution state; and a step of generating an image in which the static electricity distribution state of the substrate overlaps on the operation image of the substrate 10.

While the present inventive concept has been shown and described with reference to exemplary embodiments thereof, it will be apparent to those of ordinary skill in the art that various changes in form and detail may be made therein without departing from the spirit and scope of the inventive concept as defined by the following claims.

What is claimed is:

1. An apparatus for measuring static electricity on a substrate, comprising:
a measuring unit configured to measure first static electricity information from the substrate;
an information processing unit configured to calculate a static electricity distribution state of the substrate using the first static electricity information; and
a display unit configured to display a graphic image representing the static electricity distribution state,
wherein the information processing unit includes:
a calculating unit configured to estimate second static electricity information using the first static electricity information; and
a controller configured to calculate the static electricity distribution state of the substrate using the first static electricity information and the second static electricity information.

2. The apparatus of claim 1, wherein the information processing unit further includes an image output unit configured to generate the graphic image.

3. The apparatus of claim 1, wherein the graphic image includes numbers, a color, a combination of colors, a three-dimensional chart, or contour lines.

4. The apparatus of claim 1, further comprising:
a driving unit configured to operate the substrate so that an operation image is displayed on the substrate.

5. The apparatus of claim 4, further comprising:
a photographing unit configured to photograph the operation image of the substrate,
wherein the controller matches the operation image of the substrate and the static electricity distribution state to generate a composite image of the operation image of the substrate and the static electricity distribution state, wherein the graphic image includes the composite image.

6. The apparatus of claim 5, further comprising:
a memory unit configured to store the static electricity distribution state and the operation image of the substrate.

7. The apparatus of claim 1, wherein the measuring unit includes a base plate and a plurality of static electricity sensors, wherein the plurality of the static electricity sensor is arranged in a matrix form having a plurality of rows and a plurality of columns and is disposed on the base plate.

8. The apparatus of claim 7, wherein a size of the base plate corresponds to a size of the substrate.

9. The apparatus of claim 7, further comprising:
a camera disposed on the base plate.

10. The apparatus of claim 1, wherein the measuring unit includes at least four static electricity sensors arranged in a form of a quadrangle, each static electricity sensor being positioned at a corresponding corner of the quadrangle.

11. The apparatus of claim 10, wherein the calculating unit estimates static electricity information of a predetermined point located within the quadrangle using static electricity information measured by the first to fourth static electricity sensors.

12. The apparatus of claim 10, wherein when one of at least four static electricity sensors is defective, the calculating unit estimates static electricity information of the defective static electricity sensor using electricity information of a plurality of static electricity sensors, wherein the plurality of the static electricity sensors is adjacent to the defective static electricity sensor.

13. The apparatus of claim 12, wherein a number of the plurality of the static electricity that is adjacent to the defective static electricity sensor is equal to or greater than three.

14. A method for measuring static electricity, the method comprising:
disposing a measuring unit including a plurality of static electricity sensors on a substrate;
measuring first static electricity information using the plurality of the static electricity sensors, wherein each static electricity sensor measure the static electricity information from a corresponding sensing region of the substrate;
estimating second static electricity information of a non-sensing region adjacent to the corresponding sensing region using the first static electricity information; and
calculating a static electricity distribution state of the substrate by combining the first static electricity information and the second static electricity information.

15. The method of claim 14, further comprising:
displaying the static electricity distribution state in various graphic image.

16. The method of claim 15, wherein the graphic image include numbers, a color, a combination of colors, a three-dimensional chart, or contour lines.

17. The method of claim 14, further comprising:
displaying an operation image using the substrate by operating the substrate; and
photographing the operation image of the substrate.

18. The method of claim 17, further comprising:
matching the calculated static electricity distribution state and the operation image of the substrate to generate a composite image of the static electricity distribution state and the operation image of the substrate.

19. The method of claim 18, further comprising displaying the composite image.

20. The method of claim 14, wherein the estimating of the second static electricity information includes performing an interpolation method using the first static electricity information.
